(19) United States
(12) Patent Application Publication
(10) Pub. No.: US 2025/0094675 A1
(43) Pub. Date: Mar. 20, 2025

(54) METHOD, APPARATUS AND SYSTEM FOR GROUNDING INTERMEDIATE REPRESENTATIONS WITH FOUNDATIONAL AI MODELS FOR ENVIRONMENT UNDERSTANDING

(71) Applicant: SRI International, Menlo Park, CA (US)

(72) Inventors: Han-Pang CHIU, West Windsor, NJ (US); Karan SIKKA, Robbinsville, NJ (US); Louise YARNELL, San Mateo, CA (US); Supun SAMARASEKERA, Skillman, NJ (US); Rakesh KUMAR, West Windsor, NJ (US)

(21) Appl. No.: 18/884,473

(22) Filed: Sep. 13, 2024

Related U.S. Application Data
(60) Provisional application No. 63/538,439, filed on Sep. 14, 2023.

(51) Int. Cl. G06F 30/27; G06F 30/13

(52) U.S. Cl. CPC G06F 30/27; G06F 30/13

(57) ABSTRACT

A method, apparatus, and system for developing an understanding of at least one perceived environment includes determining semantic features and respective positional information of the semantic features from received data related to images and respective depth-related content of the at least one perceived environment on the fly as changes in the received data occur, for each perceived environment, combining information of the determined semantic features with the respective positional information to determine a compact representation of the perceived environment which provides information regarding positions of the semantic features in the perceived environment and at least spatial relationships among the sematic features, for each of the at least one perceived environments, combining information from the determined intermediate representation with information stored in a foundational model to determine a respective understanding of the perceived environment, and outputting an indication of the determined respective understanding.

### CROSS-REFERENCE TO RELATED APPLICATIONS

This application claims benefit of and priority to U.S. Provisional Patent Application Ser. No. 63/538,439, filed Sep. 14, 2023, which is herein incorporated by reference in its entirety.

### GOVERNMENT RIGHTS

This invention was made with Government support under contract number HR001123C0089 awarded by Defense Advanced Research Projects Agency (DARPA). The Government has certain rights in this invention.

### FIELD OF THE INVENTION

Embodiments of the present principles generally relate to the learning and understanding of a subject environment and, more particularly, to a method, apparatus and system for understanding a perceived environment by grounding an intermediate representation of the perceived environment with a foundational machine learning model.

### BACKGROUND

State-of-the-art (SOTA) autonomous robots rely on deep reinforcement learning (DRL) that correlates a robot's sensor data directly to the sensor's actions. However, in such arrangements, robots cannot explain their step-by-step behaviors relative to the task and especially the environment. Such an arrangement also limits natural and efficient two-way communication and collaboration between humans and robots. Therefore, humans today still need to play a dominant role for collaboration in these tasks and the learning of an environment, allowing only limited autonomy for robots.

### SUMMARY

Embodiments of the present principles provide a method, apparatus, and system for developing an understanding of at least one perceived environment.

In some embodiments, a method for developing an understanding of at least one perceived environment includes determining semantic features and respective positional information of the semantic features from received data related to images and respective depth-related content of the at least one perceived environment on the fly as changes in the received data occur, for each of the at least one perceived environments, combining information of the determined semantic features with the respective positional information to generate a compact intermediate representation of the perceived environment which provides information regarding positions of the semantic features in the perceived environment and at least spatial relationships among the sematic features, for each of the at least one perceived environments, combining information from the determined intermediate representation with information stored in a foundational model to determine a respective understanding of the perceived environment, and outputting an indication of the determined respective understanding of the perceived environment

In some embodiments, an apparatus for developing an understanding of at least one perceived environment includes a processor and a memory accessible to the processor. The memory has stored therein at least one of programs or instructions executable by the processor to configure the apparatus to determine semantic features and respective positional information of the semantic features from received data related to images and respective depth-related content of the at least one perceived environment on the fly as changes in the received data occur, for each of the at least one perceived environments, combine information of the determined semantic features with the respective positional information to generate a compact intermediate representation of the perceived environment which provides information regarding positions of the semantic features in the perceived environment and at least spatial relationships among the sematic features, for each of the at least one perceived environments, combine information from the determined intermediate representation with information stored in a foundational model to determine a respective understanding of the perceived environment, and output an indication of the determined respective understanding of the perceived environment.

In some embodiments, a system for developing an understanding of at least one perceived environment includes a foundational model and at least one machine agent including a pre-processing module, a graphing module, a processor, and a memory accessible to the processor, the memory having stored therein at least one of programs or instructions. In some embodiments, when the programs and instructions are executed by the processor, the machine agent is configured to, using the pre-processor module, determine semantic features and respective positional information of the semantic features from received data related to images and respective depth-related content of the at least one perceived environment on the fly as changes in the received data occur, using the graphing module, for each of the at least one perceived environments, combine information of the determined semantic features with the respective positional information to generate a compact intermediate representation of the perceived environment which provides information regarding positions of the semantic features in the perceived environment and at least spatial relationships among the sematic features, using the processor, for each of the at least one perceived environments, combine information from the determined intermediate representation with information stored in a foundational model to determine a respective understanding of the perceived environment, and output an indication of the determined respective understanding of the perceived environment.

In some embodiments, a non-transitory computer readable storage medium has stored thereon instructions that when executed by a processor perform a method for developing an understanding of at least one perceived environment including determining semantic features and respective positional information of the semantic features from received data related to images and respective depth-related content of the at least one perceived environment on the fly as changes in the received data occur, for each of the at least one perceived environments, combining information of the determined semantic features with the respective positional information to generate a compact intermediate representation of the perceived environment which provides information regarding positions of the semantic features in the perceived environment and at least spatial relationships among the sematic features, for each of the at least one perceived environments, combining information from the determined intermediate representation with information stored in a foundational model to determine a respective understanding of the perceived environment, and outputting an indication of the determined respective understanding of the perceived environment.

Other and further embodiments in accordance with the present principles are described below.

### BRIEF DESCRIPTION OF THE DRAWINGS

So that the manner in which the above recited features of the present principles can be understood in detail, a more particular description of the principles, briefly summarized above, may be had by reference to embodiments, some of which are illustrated in the appended drawings. It is to be noted, however, that the appended drawings illustrate only typical embodiments in accordance with the present principles and are therefore not to be considered limiting of its scope, for the principles may admit to other equally effective embodiments.

FIG. 1 depicts a high-level block diagram of a shared understanding for wide-area, human-robot collaboration (SUWAC) system in accordance with at least one embodiment of the present principles.

FIG. 2 depicts a functional diagram of an embodiment of a functionality of a SUWAC system in accordance with at least one embodiment of the present principles.

FIG. 3 depicts a high-level block diagram of a functional architecture of a graph representation module of the SUWAC system of FIG. 1 in accordance with an embodiment of the present principles.

FIG. 4 depicts an example of a hierarchical scene graph in accordance with an embodiment of the present principles.

FIG. 5 depicts a single-layer capability graph in accordance with an embodiment of the present principles.

FIG. 6 depicts a flow diagram of a flow diagram of a method 600 for developing an understanding of at least one perceived environment in accordance with an embodiment of the present principles.

FIG. 7 depicts a high-level block diagram of a computing device suitable for use with a SUWAC system in accordance with embodiments of the present principles.

FIG. 8 depicts a high-level block diagram of a network in which embodiments of a SUWAC system in accordance with the present principles can be applied.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present principles generally relate to methods, apparatuses and systems for developing an understanding of at least one perceived environment. In the embodiments of the present principles the understanding of the perceived environments are determined to enable human-machine collaboration for learning a perceived environment. While the concepts of the present principles are susceptible to various modifications and alternative forms, specific embodiments thereof are shown by way of example in the drawings and are described in detail below. It should be understood that there is no intent to limit the concepts of the present principles to the particular forms disclosed. On the contrary, the intent is to cover all modifications, equivalents, and alternatives consistent with the present principles and the appended claims. For example, although embodiments of the present principles will be described primarily with respect to specific graphing applications, such as scene graphs and knowledge graphs, embodiments of the present principles can be implemented with substantially any graphing technique that can graphically represent a perceived environment.

In the description herein, the phrase “understanding of a perceived environment” is intended to describe an instance in which an agent (machine and/or human) of a SUWAC system/network of the present principles, determines/learns details of at least the identification of objects and the locations of the objects in an environment in which at least data related to the objects and positions of the objects in the environment has been received. In some embodiments, an understanding of a perceived environment as it relates to the present principles can further include learning/knowing the properties of objects, relationships between objects whether positional or functional, and/or learning/knowing the capabilities of agents (e.g., machine/robot and or human agents) of a SUWAC system/network of the present principles in a respective environment.

In the description herein, the phrase “common sense knowledge” is intended to describe data/information known to/stored by a foundational model, such as a large language model, that includes knowledge that can be typically deduced by a human having life experiences. For example, if there is a need to locate a laptop computer, common sense knowledge in a foundational model can include that the top of a desk would be a good place to locate a laptop computer. In another example, if there is a need to locate an apple, common sense knowledge in a foundational model can include that a refrigerator and/or the top of a counter in a kitchen would be a good place to locate a laptop computer.

Embodiments of the present principles provide explicit models of a perceived environment and task-relevant knowledge. Such modeling of the present principles enables seamless collaboration between the explicit models and a foundational machine learning model, such as a large language model (LLM), which provides “common sense” knowledge relating to the perceived environment, to enable the determination of an understanding of the perceived environment. In some embodiments, the determined understanding can then be shared to provide effective communication between humans and machine agents, such as mobile robots, to perform time-critical tasks, including but not limited to environment learning/understanding for tasks such as search and rescue and disaster relief. In accordance with the present principles, explicit models of the operating environment and task-relevant knowledge, in some embodiments including but not limited to, user-defined rules, instructions, human modeling, and platform modeling, are developed and utilized for understanding at least one perceived environment for human-robot collaboration.

In embodiments of the present principles, an agent (e.g., a robot-a machine agent, or a virtual agent to assist a human-a human agent) learns to build a novel hierarchical, compact graph representation of a perceived environment. Such hierarchical graph representation of the present principles can be used for respective decision-making processes. Embodiments of a hierarchical graph representation of the present principles are described in commonly-owned U.S. patent application Ser. No. 17/554,671, which is hereby incorporated herein by reference in its entirety.

For example, in such embodiments of the present principles a shared understanding for wide-area, human-robot collaboration (SUWAC) system of the present principles can implement a hierarchical scene graph (e.g., a hierarchical semantic scene graph) for shared understanding between humans and robots. In some embodiments, using semantic scene understanding techniques, such as AI-based semantic scene understanding techniques, an agent of a SUWAC system of the present principles can dynamically construct a hierarchical semantic scene graph (e.g., a shared world model) of a perceived environment from each new observation (i.e., using equipped sensors and a processor(s) of the agent). That is, a compact, intermediate representation of a perceived environment, such as a hierarchical semantic scene graph of a perceived environment, can be generated on the fly, that is, as a perception (e.g., data collected for an environment) of an environment changes, and/or, in some embodiments, continuously.

The compact, intermediate representation (e.g., semantic graph) of the present principles is able to encode objects and their relationships in at least 3D space and across time. Based on the determined graph, the agent learns and memorializes the location of objects in the scene and what kind of objects are in the scene. In embodiments of the present principles, robots and humans can then effectively communicate through multi-modal interaction, including, but not limited to, voice, gesture, and gaze. For example, a robot can translate findings into graphics, geo-located icons, and text messages for humans to view on a device, such as a tablet or wearable Augmented Reality (AR) glasses. In some embodiments, accurate overlay of icons on geo-located objects can be viewed via AR glasses.

In some embodiments, robots and humans can also interact via voice, based on a shared understanding of the environment. In such embodiments, existing commercial off-the-shelf speech translation techniques can be integrated in a SUWAC system of the present principles. In some embodiments of a SUWAC system of the present principles, an AR virtual agent (i.e., with camera and headphones) can also utilize a semantic scene graph model to assist a human to see and hear timely and relevant information, as the agent collaborates time-critical missions with robots. As each agent utilizes and shares information from a respective scene graph, a shared understanding of the wide-area environment (i.e., shared world model) is then established among the group/team. In this way, humans can collaborate intuitively with robots, as the robots collaborate with other humans.

In some embodiments, a second hierarchical graph, a hierarchical knowledge graph, can further be formed based on user-defined rules/instructions and experience accumulated from past tasks and obtained during the mission. The hierarchical knowledge graph of the present principles can include platform modeling (i.e., robot capabilities, such as mobility, equipment, resources) and human modeling (i.e., capabilities, intent, skills, state, preferences) as well as historical data for objects and agents in a perceived environment. Using a hierarchical knowledge graph of the present principles, a machine agent (e.g., robot) can further be informed of prior information relating to a perceived environment from any data source or knowledge information from another agent. A robot's individual decision making can be improved by applying knowledge related to perceived entities in an environment, including knowledge regarding behaviors of an agent in a different environment. For example, a ground robot searching for a victim in a collapsed building can be trained to understand that the victim can be concealed on the other side of a fallen wall and notify a highspeed drone teammate to check. In such applications when the ground robot and drone converge to identify victim locations accurately, a trustable relationship for shared control between humans and robots is built.

In some embodiments, to further enhance a SUWAC system of the present principles, foundational models, such as large language models (LLMs), are leveraged to refine, augment, and update both types of hierarchical graphs (e.g., scene graphs and knowledge graphs) dynamically during a mission. That is, LLMs have the capacity to provide “common sense” knowledge about a perceived world (i.e., scene graphs). For example, when an agent recognizes a “building,” LLMs can provide information regarding other entities and relationships that are likely to exist in contexts that include buildings, such as the recognized building, for example, noting that buildings have doors and windows, and that doors can be used to enter buildings.

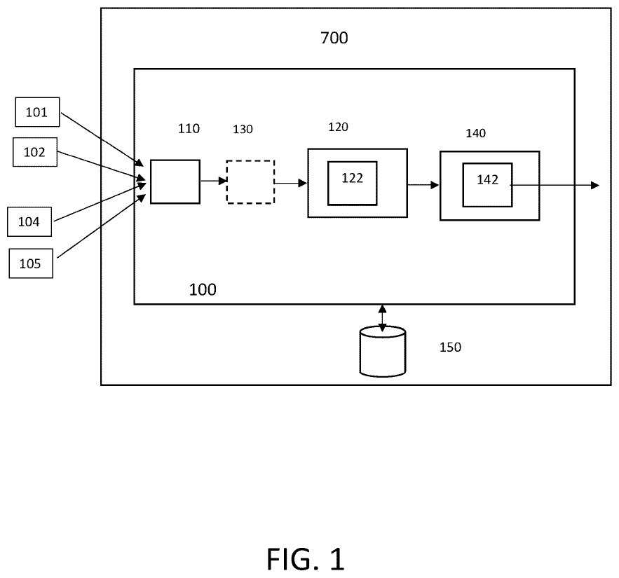

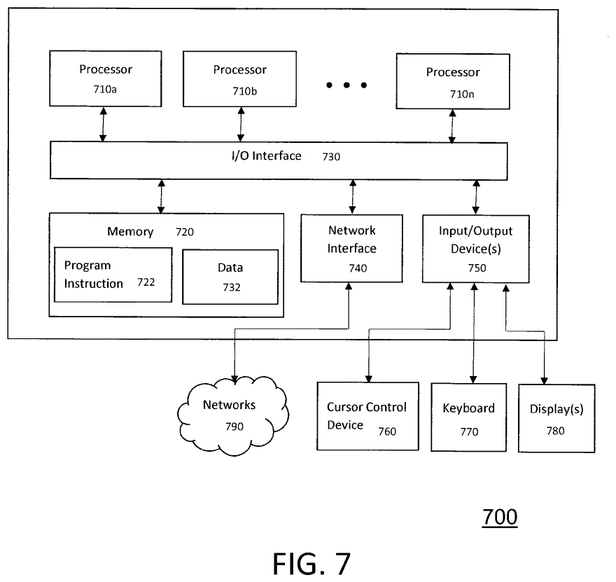

FIG. 1 depicts a high-level block diagram of a shared understanding for wide-area, human-robot collaboration (SUWAC) system 100 in accordance with at least one embodiment of the present principles. The SUWAC system 100 of FIG. 1 illustratively comprises a pre-processing module 110, a graph representation module 120, an optional ROI module 130 and a graph matching module 140. In the embodiment of FIG. 1, the SUWAC system 100 is in communication with a foundational machine learning (AI) model, illustratively a large language model (LLM) 150. As depicted in the embodiment of FIG. 1, the SUWAC system 100 can receive images from sensors for creating a perception of the environment in accordance with the present principles. For example, in the embodiment of FIG. 1, the SUWAC system 100 can receive data from at least one of a human 101, an RGB camera 102 for providing RGB image data, a Lidar sensor 104 for providing depth information of captured images, and a semantic sensor 105 for producing semantic segmentation of, for example, an input RGB image. As further depicted in FIG. 1, embodiments of a SUWAC system of the present principles, such as the SUWAC system 100 of FIG. 1, can be implemented via a computing device 700 (described in greater detail below with respect to FIG. 7) of, for example, a machine agent, including but not limited to a ground robot, and/or an unmanned aerial vehicle (UAV), in accordance with the present principles.

A SUWAC system of the present principles, such as the SUWAC system 100 of FIG. 1, enables effective multi-modal interaction among a robots and humans. This capability is important for robots/humans that need to be able to refer to specific objects in the environment, and need to show ongoing awareness of the environment as things change. In some embodiments, for efficient communication with humans, a robot can translate its findings into graphics, geo-located icons, and text messages for humans to view on tablet. In some embodiments, robots and humans can also interact via voice, based on shared understanding of the environment. In such embodiments, a robot would require the capability of translating data (e.g., video, text, graphics, and the like) into audio. In addition, in some embodiments, an AR virtual agent (with camera and headphones) can also utilize data (e.g., graph models of the present principles such as a semantic scene graph model) to assist humans to see and hear timely and relevant information. In such embodiments, accurate overlay of icons on geo-located objects can be viewed via AR glasses.

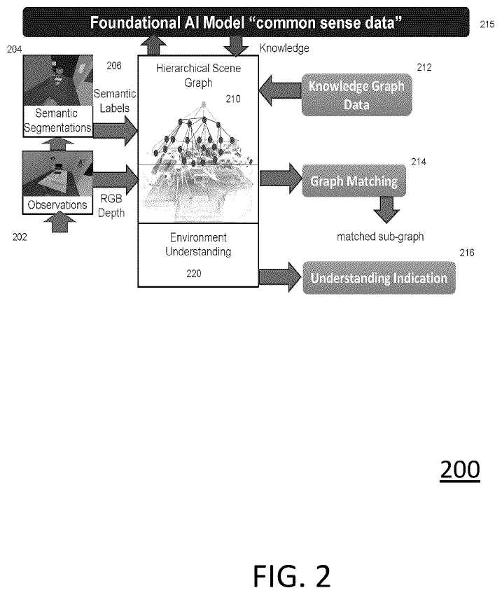

FIG. 2 depicts a functional diagram 200 of a functionality of an embodiment of a SUWAC system in accordance with at least one embodiment of the present principles. In the embodiment of FIG. 2, a perception (observation) 202 of an environment can be captured. That is and with reference back to FIG. 1, a perception of an operating environment can be captured by, for example, the RGB camera 102 for providing RGB image data and the Lidar sensor 104 for providing depth information of captured images. Although not depicted in the embodiment of FIG. 2, the human 101 can further provide information, such as rules and information about objects and agents in a perceived environment to be used to determine an understanding of the perceived environment in accordance with the present principles. For example, in some embodiments, the human 101 can provide information for creating at least one of a intermediate representation (e.g., scene graph) and/or a knowledge graph of the present principles (described in greater detail below).

As depicted in FIG. 2, the observed data can be semantically segmented 204 by, for example, the semantic sensor 105 of FIG. 1, which can provide information/data regarding at least one of the identification of objects/entities in at least one perceived environment, the location and/or depth of objects/entities in the at least one perceived environment, the capabilities of objects/entities in the at least one perceived environment, the capabilities of agents, and the like. As depicted in the embodiment of FIG. 2, from the captured observations 202 and the semantic information, such as semantic labels 206, a compact, intermediate representation 210 of the perceived/observed environment can be generated.

For example, the pre-processing module 110 of the SUWAC system 100 of FIG. 1 can determine image information from data related to the captured observations, such as features of the images and 3D object positions of the images and semantic segmentation information of images, such as a class for each pixel in the RGB images. An objective of the present principles is to learn a policy through reinforcement learning that can make effective use of three sensory inputs (e.g., the RGB camera 102, the Depth sensor 104, and the semantic sensor 105) for providing a model of the perceived environment to ultimately be used with “common sense” knowledge of a foundational model to generate an understanding of a perceived environment.

For example, in the SUWAC system 100 of FIG. 1, from the information determined in the pre-processing module 110, the graph representation module 120 can determine a compact, intermediate representation of each scene of a perceived environment for use in determining an understating of the perceived environment. A compact, intermediate representation of a perceived environment of the present principles comprises a simple structure which can be integrated with knowledge from a foundational model to generate an understanding of the perceived environment with limited processing needed.

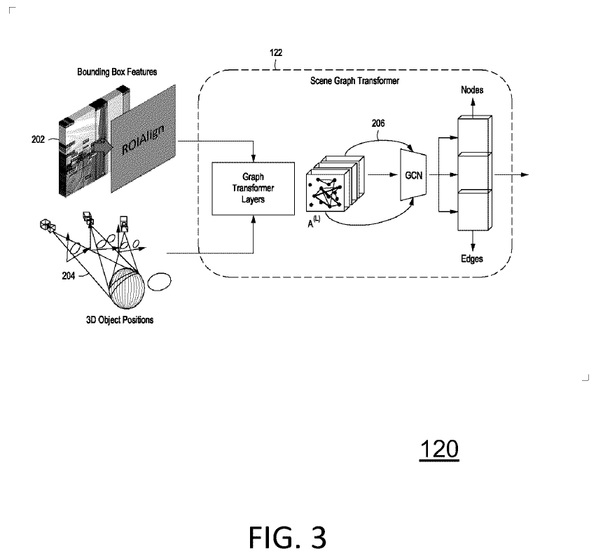

FIG. 3 depicts a high-level block diagram of a functional architecture of a graph representation module 120 of the SUWAC system 100 of FIG. 1 in accordance with an embodiment of the present principles. As depicted in FIG. 1, in some embodiments the graph representation module 120 can include a Scene graph transformer module/network 122. In the embodiment of FIG. 3, bounding boxes (e.g., ROI) can be determined, for example, by the optional ROI module 130 and features (e.g., semantic features) of each bounding box (e.g., ROI) can be determined by the pre-processing module 110. The bounding box features can then be communicated to the Scene graph transformer module/network 122. Alternatively, in some embodiments, semantic features of an entire scene can be determined. Given semantic features 202 of scenes of received content captured by, for example sensors providing at least one of image inputs to the SUMAC system 100 of FIG. 1, and respective 3D object position information 204 from, for example depth information of a captured scene, the Scene graph transformer module/network 122 can determine a scene graph representation of scenes of perceived environments, which include node and edge level features.

That is, in some embodiments the Scene graph transformer module/network 122 of the graph representation module 120 can determine a scene graph of each scene. Scene graph representations serve as a powerful way of representing image content in a simple graph structure. In embodiments of the present principles, a scene graph can consist of a heterogeneous graph in which the nodes represent objects or regions in an image and the edges represent relationships between those objects. In some embodiments, the Scene graph transformer module/network 122 can include a novel Transformer architecture, The Transformer architecture of the present principles encourages the learning of pertinent objects/semantic features and/or regions of content, in some embodiments, via an attention mechanism. In some embodiments of the present principles, an attention mechanism of the Transformer architecture of the Scene graph transformer module/network 122 can encourage the learning of pertinent objects/semantic features and/or regions of content based on a spatial relationship of the content.

In some embodiments of the present principles, a Scene Graph Transformer module of the present principles, such as the Scene graph transformer module/network 122 of FIG. 3, implements a multi-layer architecture. For example, in the Scene graph transformer module/network 122 of FIG. 2, each Graph Transformer Layer softly selects adjacency matrices (edge types) from the set of adjacency matrices of a heterogeneous graph and learns a new meta-path graph, represented by A⁽¹⁾ in FIG. 2, via a matrix multiplication of two selected adjacency matrices. In some embodiments, the soft adjacency matrix selection can be a weighted sum of candidate adjacency matrices obtained by 1×1 convolution with non-negative weights from softmax. Such determined Scene graphs can be applied to guide image synthesis. Similarly, graph neural networks (GNN), of which graph convolutional networks (GCN) seem to be the most popular type, are a class of neural networks that enable the processing of graph-structured data in a deep learning framework in accordance with the present principles.

In some embodiments, such networks work by learning a representation for the nodes and edges in the graph and iteratively refining the representation via “message passing;” i.e., sharing representations between neighboring nodes in the graph, conditioned on the graph structure. In the embodiment of FIG. 3, a graph convolutional network (GCN) 306 is implemented. To enable end-to-end graph generation and graph feature learning, in some embodiments, the GCN 306 builds up complex edges, by forming “meta-paths” from an initial set of simple geometric edge relationships. The Scene Graph Transformer module 122 learns to classify nodes and edges, while performing feature message passing using lightweight GCN operations.

For example, in some embodiments depth information from a depth image received from, for example, a Lidar sensor, can be used by, for example, the Scene graph transformer module/network 122 to estimate both the dimensions of each object, as well as the approximate location of the object. The two 6-dimensional vectors (3 dimensions and 3 coordinates) can be concatenated for each pair of nodes as the input edge representation. In the Scene graph transformer module/network 122, the GCN 306 can be implemented to simultaneously extract meaningful edges from the fully-connected graph and to perform message passing across heterogeneous edge types.

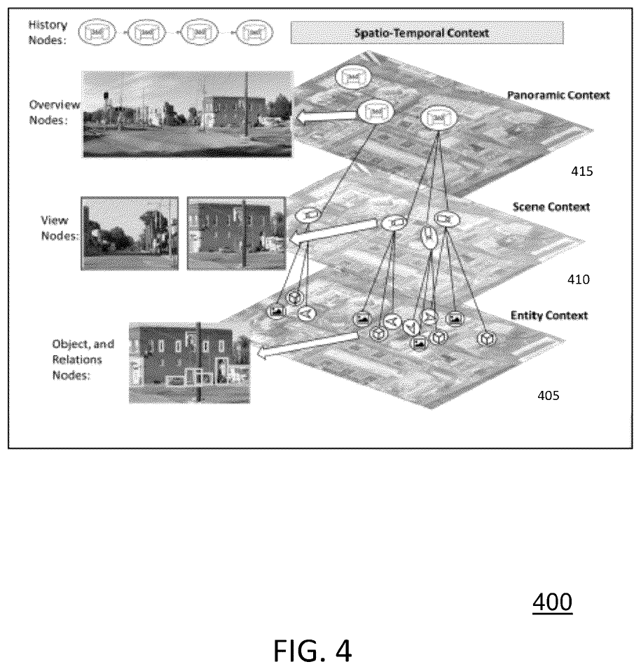

In some embodiments, a compact, intermediate representation of the present principles, such as a scene graph, can comprise a hierarchical scene graph, which encodes semantic scene entities with their 3D spatial-temporal relationships across multiple fine-grained levels. For example, FIG. 4 depicts an example of a hierarchical scene graph 400 in accordance with an embodiment of the present principles. In instances in which an RGBD camera is used as the sensor, the hierarchical scene graph can be dynamically built with each new observation from the agent to model the environment. For example, the hierarchical scene graph 400 of FIG. 4 illustratively comprises an Entity Context layer 405 which encodes objects and their 3D relationships in a single view, a Scene Context layer 410, which encodes spatial relationships across views and, a Panoramic Context layer 415, which encodes the temporal dynamics. A graph representation of the present principles, such as the scene graph 400 of FIG. 4, allows effective task planning over long-time horizons, which enables adjusting the course/action when searching for a target or when a suboptimal trajectory is being followed. For example, when searching for a target, a scene graph of the present principles enables the agent to quickly search different levels of the hierarchy for key information (i.e., observed in past) for adjusting actions, in most cases, without having to use a local camera to search again for information. In some embodiments, as each agent (i.e., both human and machine) utilizes and shares information from a respective scene graph, a shared understanding of the wide-area environment (shared world model) is then established. In this way, humans can collaborate intuitively with a robot as they do collaborate with other humans.

Alternatively or in addition, in some embodiments, a compact, intermediate representation of a perceived environment of the present principles can be generated using previously provided rules. In such embodiments, information from a human, a machine agent, and/or from a foundational model can be implemented to determine a compact, intermediate representation of a perceived environment. For example, information regarding relationships (e.g. positional relationships, functional relationships) between determined objects in a perceived environment can be used by a graph representation module of the present principles, such as the graph representation module 120 of the SUWAC system 100, of FIG. 1, to generate an intermediate representation of the perceived environment in accordance with the present principles.

Referring back to the functional diagram 200 of FIG. 2, in some embodiments the compact, hierarchical intermediate representation 210 of the present principles can be used along with a second hierarchical graph 212, a hierarchical knowledge graph, to generate an understanding 220 of the perceived environment in accordance with the present principles. That is, in some embodiments of the present principles, the graph representation module 120 of the SUWAC system 100 of FIG. 1 can determine a hierarchical knowledge graph using information regarding capabilities and functions of an agent and/or humans of a network. That is, in some embodiments, the graph representation module 120 can generate a hierarchical knowledge graph, which includes platform modeling (robot teammates' capabilities, such as mobility, equipment, resources) and human modeling (such as capabilities, intent, skills, state, preferences). In some embodiments, such information can be received from an agent of another network/system or from the human 101 of the SUWAC system 100 of FIG. 1. Alternatively or in addition, in some embodiments, such information can be retrieved from a foundational model, such as the LLM 150 of FIG. 1.

A hierarchical knowledge graph of the present principles can implement both procedural logic and self-learned prior knowledge elements that can be composed in different ways to solve a new task in a dynamic environment. In some embodiments, the knowledge of a hierarchical knowledge graph can be incorporated at different granularity layers. That is, high-level task-shared models in the hierarchical knowledge graph can operate on increasingly symbolic information, while low-level task-specific models based on sensor data can be rapidly adapted without affecting higher-level models. For example, a common task knowledge rule can recite: “A suspect can hide behind a large object”, which can be encoded at the high-level in the hierarchical knowledge graph. This rule can be generalized across different task-contexts, based on abstracted symbols (nodes: a large object, a suspect) and their relationships (edges: behind). Lower layers in the hierarchical knowledge graph can provide information at different semantic levels based on sensor data, such as which perceived objects can be sufficiently large to cover the suspect, and which large objects typically exist in the current environment. The relationships can also be defined more precisely as geometric relationships between entities (i.e., “hide behind” means “at the back” and “close to”, and “close to” means under 1 meter).

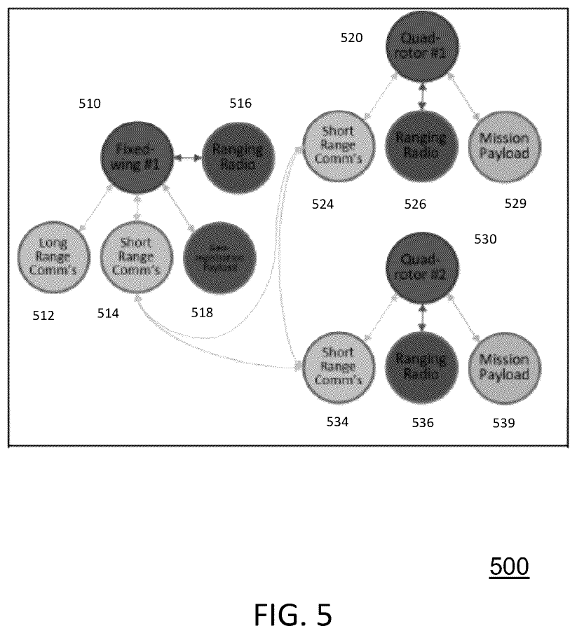

In some embodiments, a hierarchical knowledge graph of the present principles can include a capability graph to encode prior knowledge for information sharing as a single-layer graph. For example, FIG. 5 depicts a single-layer capability graph 500 in accordance with an embodiment of the present principles. The capability graph 500 of FIG. 5 illustratively comprises a fixed-winged aerial vehicle 510, a first quad-rotor aerial vehicle 520, and a second quad-rotor aerial vehicle 530. The capability graph 500 of FIG. 5 graphs the functionality of the fixed-winged aerial vehicle 510, the first quad-rotor aerial vehicle 520, and the second quad-rotor aerial vehicle 530. For example and as depicted in FIG. 5, the fixed-winged aerial vehicle 510 is capable of long-range comm's 512, short-range comm's 514, has a ranging radio 516, and geo-registration payload 518. In the embodiment of FIG. 5, the first quad-rotor aerial vehicle 520 is capable of short-range comm's 524, has a ranging radio 526, and a mission payload 529 and the second quad-rotor aerial vehicle 530 is capable of short-range comm's 534, has a ranging radio 536, and a mission payload 539. By implementing even a single-layer hierarchical knowledge graph of the present principles, information sharing of agent capabilities can be implemented. That is, a hierarchical knowledge graph of the present principles informs each agent of the capabilities of each member. The knowledge of the capabilities of machine agents in a perceived environment can be implemented to generate an understanding of the perceived environment in accordance with the present principles.

In some embodiments, the information from the compact, intermediate representation of a perceived environment of the present principles can be combined with information from the knowledge graph of the present principles. For example, with back to the functional diagram 200 of FIG. 2 and the SUWAC 110 of FIG. 1, in the SUWAC system 100 of FIG. 1, the graph matching module 140 can perform graph matching 214 of at least portions of a hierarchical scene graph of the present principles with portions of hierarchical knowledge graph of the present principles. The matching results highlight meaningful entities and relationships and integrates additional context into the agent's perception of a current scene of a perceived environment based on a capability of an agent. That is, the graph matching module 140 of the SUWAC system 100 of FIG. 1 can provide knowledge distillation around current observations that can be critical to efficiency in performing tasks. A graph matching module of the present principles, such as the graph matching module 140 of the SUWAC system 100 of FIG. 1, can implement learning methods or heuristics to perform matching between perceived entities in a hierarchical scene graph with corresponding nodes from a hierarchical knowledge graph. In some embodiments, the matching performed by the graph matching module 140 can generate a semantic graph representation including tagged novel entities/characteristics, in which each scene entity visible by an agent is supported by context and prior knowledge derived from a portion (subgraph) of the hierarchical knowledge graph. In some embodiments, a semantic graph representation of the present principles encodes semantic entities and their spatial relationships at multiple layers of fidelity.

In some embodiments, to manage unexpected patterns and/or unseen entities, the graph matching module 140 can further associate the unforeseen entity/event with a similar stored knowledge, e.g., “smokescreen” (unforeseen) with “wall” (seen). In some embodiments, an association can be achieved by finding a seen class which contains a nearest feature vector in an embedding space generated by a pretrained model. That is and as depicted in the SUWAC system 100 of FIG. 1, the graph matching module 140 can include a machine learning system 142 for determining a machine learning model of the present principles. In some embodiments, the machine learning system 142 of the graph matching module 140 can train a machine learning model to create vector representations of entities in a scene visible by at least one agent (i.e., as depicted in semantic graph and/or at least one scene graph and/or knowledge graph) and by embedding the created vectors into an embedding space to preserve similarities (e.g., cosine similarities) among the vector representations of the entities. As such, when searching for and/or attempting to classify an unseen entity, an association can be achieved by finding a previously seen entity/class which contains a nearest feature vector to the unseen entity in the embedding space generated by the machine learning model.

In some embodiments of the present principles, an unforeseen entity can also be inferred based on similar visual observations and prior knowledge via compositional generalization, e.g., “a muddy road” (unforeseen) with “road” (seen) and “mud” (seen).

Referring back to the functional diagram 200 of FIG. 2, in some embodiments of the present principles, knowledge (“common sense data) 215 from a foundational machine learning (AI) model can be used to supplement the information determined by a SUWAC of the present principles to generate an understanding 220 of the perceived environment in accordance with the present principles. For example, for the SUWAC system 100 of FIG. 1, the LLM 150 is implemented to refine and augment the hierarchical graphs of the present principles with an emphasis on action planning. That is, in some embodiments, the “common sense” knowledge of the LLM 150 can be used to (1) to reduce the uncertainty about the perceived entities and their attributes, (2) to augment scene entities (with their attributes) and relationships among entities using contextual commonsense knowledge, and (3) to discover relevant properties of entities that are useful for action planning. In the embodiments of FIG. 1 and FIG. 2, data 215 from the foundational model (e.g., the LLM 150) is implemented by the SUWAC system 100 of FIG. 1 as a great resource of “common-sense” knowledge about the world. For example, one could prompt/query the SUWAC system 100 with the text, “I am in a room indoors. I see a microwave and a refrigerator. What other objects are in the room?”; the LLM 150 might recognize the context as a kitchen, and respond, “There is a stovetop and a refrigerator.” Such objects and information can then be added to, for example, an intermediate representation of the perceived environment.

By utilizing the commonsense knowledge from foundational models, such as LLMs, an agent implementing the SUWAC system 100 of the present principles can have a better understanding and prediction of the perceived environment in which a task to be performed. For example, when an agent recognizes a building, the SUWAC system 100 can be queried about other entities and relationships that are likely to exist in contexts that include buildings and using information from the LLM 150, the SUWAC system 100 can respond that buildings have doors and windows, that doors can be used to enter buildings, etc. Using the information from the LLM 150, an intermediate representation, such as hierarchical scene graph, of a SUWAC system of the present principles encodes semantically meaningful spatial arrangements of scene objects that the agent can expect to be present in the environment and can update the information in the scene graph accordingly. In some embodiments of the present principles, context from a hierarchical graph of the present principles can be used to generate LLM queries by filling in structured prompts in, for example, an interface of the computing device (e.g., 700 of FIG. 7) of a machine agent. For example, the previous example of asking about objects in a kitchen can be generalized to a template for asking about a generic scene, i.e., “I see objects X, Y, and Z. What other objects can I see?”.

The intermediate representations of the perceived environment(s) determined using a SUWAC of the present principles, such as the SUWAC 100 of FIG. 1, in conjunction with the information from a foundational model, such as the LLM 150 of FIG. 1, as described above, can be used to generate an understanding of a perceived environment in accordance with the present principles. Such generated understanding can be used, for example, to navigate an agent through the at least one perceived environment using information in the developed understanding of the at least one perceived environment. In embodiments of the present principles, an agent can navigate through the at least one perceived environment to identify at least one of an object or a location in the at least one perceived environment. That is in accordance with the present principles, compact, intermediate representations of an environment determined from observations of the environment can be supplemented with “common sense” data from a foundational machine learning (AI) model to generate a high-level understanding of the perceived environment.

Referring back to the functional diagram 200 of FIG. 2, in some embodiments of the present principles, an indication 216 of the determined understanding of the perceived environment can be output by a SUWAC system of the present principles, such as the SUWAC system 100 of FIG. 1. In some embodiments, an indication of the determined understanding of the perceived environment can include at least one of a representation of the perceived environment annotated using information from at least the intermediate representation and the foundational model, a navigation plan to enable an agent to navigate the perceived environment determined from the determined respective understanding, or a next step of a task to be completed by the agent in the perceived environment. For example, in some embodiments, a pictorial representation of the perceived environment can be generated including annotated objects and relationships between the objects using information from at least the determined intermediate representation and the foundational model. Such pictorial representation can then be output, for example but not necessarily, by the graphing module 140 of the SUWAC system 100 of FIG. 1, to a display or output device; for example, a display of the computing device 700 or any other presentation means of the computing device 700 or an associated machine agent.

In some embodiments of the present principles, a machine agent or human agent can have the need to be directed to a specific location in a perceived environment. An understanding of the perceived environment determined in accordance with the present principles described herein can be used to determine a path through the perceived environment for the machine agent or the human agent. For example, in some embodiments a path through a perceived environment can be determined using the understanding of the perceived environment of the present principles, for example but not necessarily, by the graphing module 140 of the SUWAC system 100 of FIG. 1. In some embodiments, an indication of the determined path can then be communicated to the machine agent or the human agent. Alternatively or in addition, in some embodiments, the machine agent or the human agent can be directed/controlled to follow the determined path.

In some embodiments of the present principles, an understanding of a perceived environment of the present principles can be used to determine a next step of a task to be completed by the agent in the perceived environment. For example, in some embodiments, information from at least an intermediate representation of a perceived environment and knowledge from a foundational model can be used to determine a task that is being performed by an agent in the perceived environment. In such embodiments, the information from the intermediate representation of the perceived environment and the knowledge from the foundational model can be used to determine a next step in the task that is being performed by an agent in the perceived environment. In some embodiments, an indication of the next step in the task can then be communicated to a machine agent or a human agent performing the identified task. Alternatively or in addition, in some embodiments, the machine agent or the human agent can be directed/controlled to perform the determined next step.

In some embodiments of the present principles, a foundational model, such as the LLM 150 of FIG. 1, can be fine-tuned using information from a SUWAC system of the present principles, such as the SUWAC system 100 of FIG. 1. For example, in such embodiments, the LLM 150 can be fed information of a portion of, for example, a hierarchical graph of the present principles, and can be trained on the information (entities, connections, associations, etc.) of only that portion of the hierarchical graph. A key idea in such embodiments is to directly feed inputs from a sensor (such as hierarchical scene graphs) to the LLM, instead of converting the information to a prompt. The LLM 150 is then finetuned by the SUWAC system 100 on a small set of examples. A key difference in such embodiments as compared to standard learning for the LLM 150 is that the LLM is trained/fine-tuned using only a few parameters (2-3% and referred to as adapters).

In some embodiments of the present principles, human-robot interactions can be coordinated using path planning and motion planning for the robot, as when a robot needs to convey that it is about to move over. Agents (such as a robot or a virtual agent to assist a human) that have these abilities will be able to communicate more efficiently, often using just a few words augmented with multimodal signals. Therefore, information transfer between humans and robots can evolve from being a sequence of individual communicative actions to more continuous and trustable interactions.

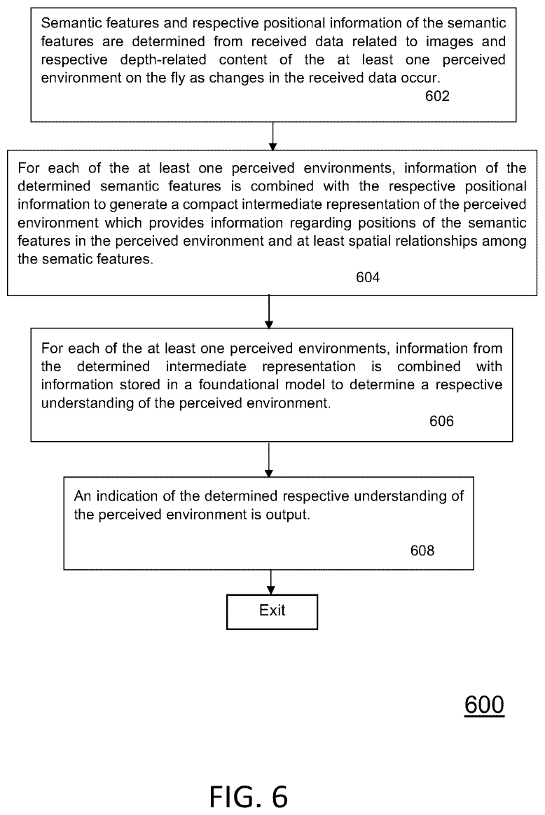

FIG. 6 depicts a flow diagram of a method 600 for developing an understanding of at least one perceived environment in accordance with an embodiment of the present principles. The method 600 can begin at 602 during which semantic features and respective positional information of the semantic features are determined from received data related to images and respective depth-related content of the at least one perceived environment on the fly as changes in the received data occur. The method 600 can proceed to 604.

At 604, for each of the at least one perceived environments, information of the determined semantic features is combined with the respective positional information to generate a compact intermediate representation of the perceived environment which provides information regarding positions of the semantic features in the perceived environment and at least spatial relationships among the sematic features. The method 600 can proceed to 606.

At 606, for each of the at least one perceived environments, information from the determined intermediate representation is combined with information stored in a foundational model to determine a respective understanding of the perceived environment. The method 600 can proceed to 608.

At 608, an indication of the determined respective understanding of the perceived environment is output. The method 600 can then be exited.

In some embodiments, the method can further include navigating an agent through the at least one perceived environment using the developed understanding of the at least one perceived environment to locate at least one of an object or a location in the at least one perceived environment.

In some embodiments, the compact intermediate representation of the perceived environment is generated using at least one of a neural network or predetermined rules.

In some embodiments, the data related to the images and the respective depth-related content of the at least one perceived environment is received from at least one of a human, an agent or at least one sensor capable of capturing image content and depth information of the at least one perceived environment.

In some embodiments, the intermediate representation comprises at least one of a hierarchical scene graph, which encodes the semantic features with their 3D spatial-temporal relationships across multiple levels or a hierarchical knowledge graph, which models at least one agent used in developing an understanding of the at least one perceived environment and capabilities of the at least one agent.

In some embodiments, the foundational model comprises a large language model, which provides common sense knowledge for the at least one perceived environment.

In some embodiments, the indication comprises at least one of a representation of the perceived environment annotated using information from the determined respective understanding, a navigation plan to enable an agent to navigate the perceived environment determined from the determined respective understanding, or a next step of a task to be completed by the agent in the perceived environment.

In some embodiments, an apparatus for developing an understanding of at least one perceived environment includes a processor and a memory accessible to the processor. The memory can have stored therein at least one of programs or instructions executable by the processor to configure the apparatus to determine semantic features and respective positional information of the semantic features from received data related to images and respective depth-related content of the at least one perceived environment on the fly, that is as changes in the received data occur, for each of the at least one perceived environments, combine information of the determined semantic features with the respective positional information to generate a compact intermediate representation of the perceived environment which provides information regarding positions of the semantic features in the perceived environment and at least spatial relationships among the sematic features, for each of the at least one perceived environments, combine information from the determined intermediate representation with information stored in a foundational model to determine a respective understanding of the perceived environment, and output an indication of the determined respective understanding of the perceived environment.

In some embodiments, a system for developing an understanding of at least one perceived environment includes, comprising a foundational model and at least one machine agent comprising a pre-processing module, a graphing module, a processor, and a memory accessible to the processor. The memory can have stored therein at least one of programs or instructions executable by the processor to configure the machine agent to using the pre-processor module, determine semantic features and respective positional information of the semantic features from received data related to images and respective depth-related content of the at least one perceived environment on the fly, that is as changes in the received data occur, using the graphing module, for each of the at least one perceived environments, combine information of the determined semantic features with the respective positional information to generate a compact intermediate representation of the perceived environment which provides information regarding positions of the semantic features in the perceived environment and at least spatial relationships among the sematic features, using the processor, for each of the at least one perceived environments, combine information from the determined intermediate representation with information stored in a foundational model to determine a respective understanding of the perceived environment, and output an indication of the determined respective understanding of the perceived environment.

In some embodiments, a non-transitory computer readable storage medium has stored thereon instructions that when executed by a processor perform a method for developing an understanding of at least one perceived environment including determining semantic features and respective positional information of the semantic features from received data related to images and respective depth-related content of the at least one perceived environment on the fly, that is as changes in the received data occur, for each of the at least one perceived environments, combining information of the determined semantic features with the respective positional information to generate a compact intermediate representation of the perceived environment which provides information regarding positions of the semantic features in the perceived environment and at least spatial relationships among the sematic features, for each of the at least one perceived environments, combining information from the determined intermediate representation with information stored in a foundational model to determine a respective understanding of the perceived environment, and outputting an indication of the determined respective understanding of the perceived environment.

As depicted in FIG. 1, embodiments of a SUWAC system of the present principles, such as the SUWAC system 100 of FIG. 1, can be implemented in a computing device 700 in accordance with the present principles. That is, in some embodiments, data can be communicated to, for example, the pre-processing module 110 of the SUWAC system 100 of FIG. 1 using the computing device 700 via, for example, any input/output means associated with the computing device 700. Data associated with a graphical representation formulation system in accordance with the present principles can be presented to a user using an output device of the computing device 700, such as a display, a printer or any other form of output device.

For example, FIG. 7 depicts a high-level block diagram of a computing device 700 suitable for use with embodiments of a SUWAC system in accordance with the present principles, such as the SUWAC system 100 of FIG. 1. In some embodiments, the computing device 700 can be configured to implement methods of the present principles as processor-executable program instructions 722 (e.g., program instructions executable by processor(s) 710) in various embodiments.

In the embodiment of FIG. 7, the computing device 700 includes one or more processors 710a-710n coupled to a system memory 720 via an input/output (I/O) interface 730. The computing device 700 further includes a network interface 740 coupled to I/O interface 730, and one or more input/output devices 750, such as cursor control device 760, keyboard 770, and display(s) 780. In various embodiments, a user interface can be generated and displayed on display 780. In some cases, it is contemplated that embodiments can be implemented using a single instance of computing device 700, while in other embodiments multiple such systems, or multiple nodes making up the computing device 700, can be configured to host different portions or instances of various embodiments. For example, in one embodiment some elements can be implemented via one or more nodes of the computing device 700 that are distinct from those nodes implementing other elements. In another example, multiple nodes may implement the computing device 700 in a distributed manner.

In different embodiments, the computing device 700 can be any of various types of devices, including, but not limited to, a personal computer system, desktop computer, laptop, notebook, tablet or netbook computer, mainframe computer system, handheld computer, workstation, network computer, a camera, a set top box, a mobile device, a consumer device, video game console, handheld video game device, application server, storage device, a peripheral device such as a switch, modem, router, or in general any type of computing or electronic device.

In various embodiments, the computing device 700 can be a uniprocessor system including one processor 710, or a multiprocessor system including several processors 710 (e.g., two, four, eight, or another suitable number). Processors 710 can be any suitable processor capable of executing instructions. For example, in various embodiments processors 710 may be general-purpose or embedded processors implementing any of a variety of instruction set architectures (ISAs). In multiprocessor systems, each of processors 710 may commonly, but not necessarily, implement the same ISA.

System memory 720 can be configured to store program instructions 722 and/or data 732 accessible by processor 710. In various embodiments, system memory 720 can be implemented using any suitable memory technology, such as static random-access memory (SRAM), synchronous dynamic RAM (SDRAM), nonvolatile/Flash-type memory, or any other type of memory. In the illustrated embodiment, program instructions and data implementing any of the elements of the embodiments described above can be stored within system memory 720. In other embodiments, program instructions and/or data can be received, sent or stored upon different types of computer-accessible media or on similar media separate from system memory 720 or computing device 700.

In one embodiment, I/O interface 730 can be configured to coordinate I/O traffic between processor 710, system memory 720, and any peripheral devices in the device, including network interface 740 or other peripheral interfaces, such as input/output devices 750. In some embodiments, I/O interface 730 can perform any necessary protocol, timing or other data transformations to convert data signals from one component (e.g., system memory 720) into a format suitable for use by another component (e.g., processor 710). In some embodiments, I/O interface 730 can include support for devices attached through various types of peripheral buses, such as a variant of the Peripheral Component Interconnect (PCI) bus standard or the Universal Serial Bus (USB) standard, for example. In some embodiments, the function of I/O interface 730 can be split into two or more separate components, such as a north bridge and a south bridge, for example. Also, in some embodiments some or all of the functionality of I/O interface 730, such as an interface to system memory 720, can be incorporated directly into processor 710.

Network interface 740 can be configured to allow data to be exchanged between the computing device 700 and other devices attached to a network (e.g., network 790), such as one or more external systems or between nodes of the computing device 700. In various embodiments, network 790 can include one or more networks including but not limited to Local Area Networks (LANs) (e.g., an Ethernet or corporate network), Wide Area Networks (WANs) (e.g., the Internet), wireless data networks, some other electronic data network, or some combination thereof. In various embodiments, network interface 740 can support communication via wired or wireless general data networks, such as any suitable type of Ethernet network, for example; via digital fiber communications networks; via storage area networks such as Fiber Channel SANs, or via any other suitable type of network and/or protocol.

Input/output devices 750 can, in some embodiments, include one or more display terminals, keyboards, keypads, touchpads, scanning devices, voice or optical recognition devices, or any other devices suitable for entering or accessing data by one or more computer systems. Multiple input/output devices 750 can be present in computer system or can be distributed on various nodes of the computing device 700. In some embodiments, similar input/output devices can be separate from the computing device 700 and can interact with one or more nodes of the computing device 700 through a wired or wireless connection, such as over network interface 740.

Those skilled in the art will appreciate that the computing device 700 is merely illustrative and is not intended to limit the scope of embodiments. In particular, the computer system and devices can include any combination of hardware or software that can perform the indicated functions of various embodiments, including computers, network devices, Internet appliances, PDAs, wireless phones, pagers, and the like. The computing device 700 can also be connected to other devices that are not illustrated, or instead can operate as a stand-alone system. In addition, the functionality provided by the illustrated components can in some embodiments be combined in fewer components or distributed in additional components. Similarly, in some embodiments, the functionality of some of the illustrated components may not be provided and/or other additional functionality can be available.

The computing device 700 can communicate with other computing devices based on various computer communication protocols such a Wi-Fi, Bluetooth® (and/or other standards for exchanging data over short distances includes protocols using short-wavelength radio transmissions), USB, Ethernet, cellular, an ultrasonic local area communication protocol, etc. The computing device 700 can further include a web browser.

Although the computing device 700 is depicted as a general-purpose computer, the computing device 700 is programmed to perform various specialized control functions and is configured to act as a specialized, specific computer in accordance with the present principles, and embodiments can be implemented in hardware, for example, as an application specified integrated circuit (ASIC). As such, the process steps described herein are intended to be broadly interpreted as being equivalently performed by software, hardware, or a combination thereof.

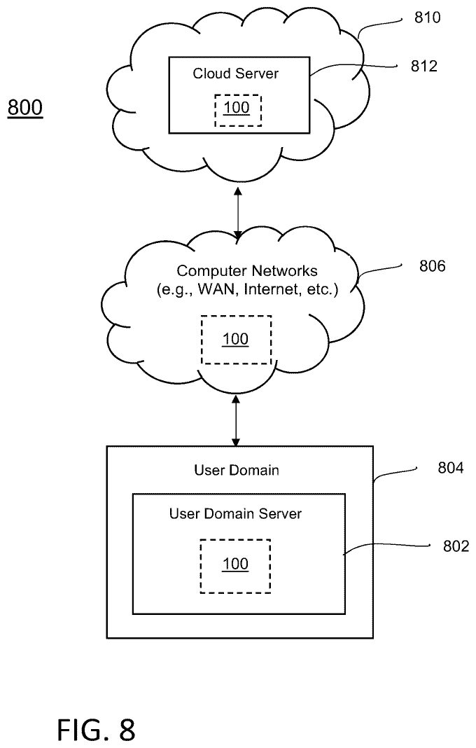

FIG. 8 depicts a high-level block diagram of a network in which embodiments of a SUWAC system in accordance with the present principles, such as the SUWAC system 100 of FIG. 1, can be applied. The network environment 800 of FIG. 8 illustratively comprises a user domain 802 including a user domain server/computing device 804. The network environment 800 of FIG. 8 further comprises computer networks 806, and a cloud environment 810 including a cloud server/computing device 812.

In the network environment 800 of FIG. 8, a system for developing an understanding of at least one perceived environment in accordance with the present principles, such as the SUWAC system 100 of FIG. 1, can be included in at least one of the user domain server/computing device 804, the computer networks 806, and the cloud server/computing device 812. That is, in some embodiments, a user can use a local server/computing device (e.g., the user domain server/computing device 804) to provide data (e.g., image data, depth data, semantic data, etc.) related to at least a portion of a respective environment for a SUWAC system of the present principles to develop an understanding of the environment in accordance with the present principles.

In some embodiments, a user can implement a SUWAC system of the present principles in the computer networks 806 to develop an understanding of at least one perceived environment in accordance with the present principles. Alternatively or in addition, in some embodiments, a user can implement a SUWAC system of the present principles in the cloud server/computing device 812 of the cloud environment 810 in accordance with the present principles. For example, in some embodiments it can be advantageous to perform processing functions of the present principles in the cloud environment 810 to take advantage of the processing capabilities and storage capabilities of the cloud environment 810. In some embodiments in accordance with the present principles, a system for developing an understanding of at least one perceived environment can be located in a single and/or multiple locations/servers/computers to perform all or portions of the herein described functionalities of a system in accordance with the present principles. For example, in some embodiments components of a the SUWAC system of the present principles, such as the pre-processing module 110 of the SUWAC system 100 of FIG. 1, can be located in one or more than one of the user domain 802, the computer network environment 806, and the cloud environment 810 for providing the functions described above either locally and/or remotely and/or in a distributed manner.

Those skilled in the art will also appreciate that, while various items are illustrated as being stored in memory or on storage while being used, these items or portions of them can be transferred between memory and other storage devices for purposes of memory management and data integrity. Alternatively, in other embodiments some or all of the software components can execute in memory on another device and communicate with the illustrated computer system via inter-computer communication. Some or all of the system components or data structures can also be stored (e.g., as instructions or structured data) on a computer-accessible medium or a portable article to be read by an appropriate drive, various examples of which are described above. In some embodiments, instructions stored on a computer-accessible medium separate from the computing device 700 can be transmitted to the computing device 700 via transmission media or signals such as electrical, electromagnetic, or digital signals, conveyed via a communication medium such as a network and/or a wireless link. Various embodiments can further include receiving, sending or storing instructions and/or data implemented in accordance with the foregoing description upon a computer-accessible medium or via a communication medium. In general, a computer-accessible medium can include a storage medium or memory medium such as magnetic or optical media, e.g., disk or DVD/CD-ROM, volatile or non-volatile media such as RAM (e.g., SDRAM, DDR, RDRAM, SRAM, and the like), ROM, and the like.

The methods and processes described herein may be implemented in software, hardware, or a combination thereof, in different embodiments. In addition, the order of methods can be changed, and various elements can be added, reordered, combined, omitted or otherwise modified. All examples described herein are presented in a non-limiting manner. Various modifications and changes can be made as would be obvious to a person skilled in the art having benefit of this disclosure. Realizations in accordance with embodiments have been described in the context of particular embodiments. These embodiments are meant to be illustrative and not limiting. Many variations, modifications, additions, and improvements are possible. Accordingly, plural instances can be provided for components described herein as a single instance. Boundaries between various components, operations and data stores are somewhat arbitrary, and particular operations are illustrated in the context of specific illustrative configurations. Other allocations of functionality are envisioned and can fall within the scope of claims that follow. Structures and functionality presented as discrete components in the example configurations can be implemented as a combined structure or component. These and other variations, modifications, additions, and improvements can fall within the scope of embodiments as defined in the claims that follow.

In the foregoing description, numerous specific details, examples, and scenarios are set forth in order to provide a more thorough understanding of the present disclosure. It will be appreciated, however, that embodiments of the disclosure can be practiced without such specific details. Further, such examples and scenarios are provided for illustration, and are not intended to limit the disclosure in any way. Those of ordinary skill in the art, with the included descriptions, should be able to implement appropriate functionality without undue experimentation.

References in the specification to “an embodiment,” etc., indicate that the embodiment described can include a particular feature, structure, or characteristic, but every embodiment may not necessarily include the particular feature, structure, or characteristic. Such phrases are not necessarily referring to the same embodiment. Further, when a particular feature, structure, or characteristic is described in connection with an embodiment, it is believed to be within the knowledge of one skilled in the art to affect such feature, structure, or characteristic in connection with other embodiments whether or not explicitly indicated.

Embodiments in accordance with the disclosure can be implemented in hardware, firmware, software, or any combination thereof. Embodiments can also be implemented as instructions stored using one or more machine-readable media, which may be read and executed by one or more processors. A machine-readable medium can include any mechanism for storing or transmitting information in a form readable by a machine (e.g., a computing device or a “virtual machine” running on one or more computing devices). For example, a machine-readable medium can include any suitable form of volatile or non-volatile memory.

In addition, the various operations, processes, and methods disclosed herein can be embodied in a machine-readable medium and/or a machine accessible medium/storage device compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium/storage device.

Modules, data structures, and the like defined herein are defined as such for ease of discussion and are not intended to imply that any specific implementation details are required. For example, any of the described modules and/or data structures can be combined or divided into sub-modules, sub-processes or other units of computer code or data as can be required by a particular design or implementation.

In the drawings, specific arrangements or orderings of schematic elements can be shown for ease of description. However, the specific ordering or arrangement of such elements is not meant to imply that a particular order or sequence of processing, or separation of processes, is required in all embodiments. In general, schematic elements used to represent instruction blocks or modules can be implemented using any suitable form of machine-readable instruction, and each such instruction can be implemented using any suitable programming language, library, application-programming interface (API), and/or other software development tools or frameworks. Similarly, schematic elements used to represent data or information can be implemented using any suitable electronic arrangement or data structure. Further, some connections, relationships or associations between elements can be simplified or not shown in the drawings so as not to obscure the disclosure.

This disclosure is to be considered as exemplary and not restrictive in character, and all changes and modifications that come within the guidelines of the disclosure are desired to be protected.

1. A method for developing an understanding of at least one perceived environment, comprising:
determining semantic features and respective positional information of the semantic features from received data related to images and respective depth-related content of the at least one perceived environment on the fly as changes in the received data occur;
for each of the at least one perceived environments, combining information of the determined semantic features with the respective positional information to generate a compact intermediate representation of the perceived environment which provides information regarding positions of the semantic features in the perceived environment and at least spatial relationships among the sematic features;
for each of the at least one perceived environments, combining information from the determined intermediate representation with information stored in a foundational model to determine a respective understanding of the perceived environment; and
outputting an indication of the determined respective understanding of the perceived environment.

2. The method of claim 1, wherein the data related to the images and the respective depth-related content of the at least one perceived environment is received from at least one of a human, an agent or at least one sensor capable of capturing image content and depth information of the at least one perceived environment.

3. The method of claim 1, wherein the intermediate representation comprises at least one of a hierarchical scene graph, which encodes the semantic features with their 3D spatial-temporal relationships across multiple levels or a hierarchical knowledge graph, which models at least one agent used in developing an understanding of the at least one perceived environment and capabilities of the at least one agent.

4. The method of claim 1, wherein the foundational model comprises a large language model, which provides common sense knowledge for the at least one perceived environment.

5. The method of claim 1, wherein the indication comprises at least one of a representation of the perceived environment annotated using information from the determined respective understanding, a navigation plan to enable an agent to navigate the perceived environment determined from the determined respective understanding, or a next step of a task to be completed by the agent in the perceived environment.

6. The method of claim 1, further comprising:
navigating an agent through the at least one perceived environment using the developed understanding of the at least one perceived environment to locate at least one of an object or a location in the at least one perceived environment.

7. The method of claim 1, wherein the compact intermediate representation of the perceived environment is generated using at least one of a neural network or predetermined rules.

8. An apparatus for developing an understanding of at least one perceived environment, comprising:
a processor; and
a memory accessible to the processor, the memory having stored therein at least one of programs or instructions executable by the processor to configure the apparatus to:
determine semantic features and respective positional information of the semantic features from received data related to images and respective depth-related content of the at least one perceived environment on the fly as changes in the received data occur;
for each of the at least one perceived environments, combine information of the determined semantic features with the respective positional information to generate a compact intermediate representation of the perceived environment which provides information regarding positions of the semantic features in the perceived environment and at least spatial relationships among the sematic features;
for each of the at least one perceived environments, combine information from the determined intermediate representation with information stored in a foundational model to determine a respective understanding of the perceived environment; and
output an indication of the determined respective understanding of the perceived environment.

9. The apparatus of claim 8, wherein the data related to the images and the respective depth-related content of the at least one perceived environment is received from at least one of a human, an agent or at least one sensor capable of capturing image content and depth information of the at least one perceived environment.

10. The apparatus of claim 8, wherein the intermediate representation comprises at least one of a hierarchical scene graph, which encodes the semantic features with their 3D spatial-temporal relationships across multiple levels or a hierarchical knowledge graph, which models at least one agent used in developing an understanding of the at least one perceived environment and capabilities of the at least one agent.

11. The apparatus of claim 8, wherein the foundational model comprises a large language model, which provides common sense knowledge for the at least one perceived environment.

12. The apparatus of claim 8, wherein the indication comprises at least one of a representation of the perceived environment annotated using information from the determined respective understanding, a navigation plan to enable an agent to navigate the perceived environment determined from the determined respective understanding, or a next step of a task to be completed by the agent in the perceived environment.

13. The apparatus of claim 8, wherein the apparatus is further configured to:
navigate an agent through the at least one perceived environment using the developed understanding of the at least one perceived environment to locate at least one of an object or a location in the at least one perceived environment.

14. The apparatus of claim 8, wherein the compact intermediate representation of the perceived environment is generated using at least one of a neural network or predetermined rules.

15. A system for developing an understanding of at least one perceived environment, comprising:
a foundational model; and
at least one machine agent, comprising:
a pre-processing module;
a graphing module;
a processor; and
a memory accessible to the processor, the memory having stored therein at least one of programs or instructions executable by the processor to configure the machine agent to:
using the pre-processor module, determine semantic features and respective positional information of the semantic features from received data related to images and respective depth-related content of the at least one perceived environment on the fly as changes in the received data occur;
using the graphing module, for each of the at least one perceived environments, combine information of the determined semantic features with the respective positional information to generate a compact intermediate representation of the perceived environment which provides information regarding positions of the semantic features in the perceived environment and at least spatial relationships among the sematic features;
using the processor, for each of the at least one perceived environments, combine information from the determined intermediate representation with information stored in a foundational model to determine a respective understanding of the perceived environment; and
output an indication of the determined respective understanding of the perceived environment.

16. The system of claim 15, wherein the data related to the images and the respective depth-related content of the at least one perceived environment is received from at least one of a human, an agent or at least one sensor capable of capturing image content and depth information of the at least one perceived environment.

17. The system of claim 15, wherein the intermediate representation comprises at least one of a hierarchical scene graph, which encodes the semantic features with their 3D spatial-temporal relationships across multiple levels or a hierarchical knowledge graph, which models at least one agent used in developing an understanding of the at least one perceived environment and capabilities of the at least one agent.

18. The system of claim 15, wherein the foundational model comprises a large language model, which provides common sense knowledge for the at least one perceived environment.

19. The system of claim 15, wherein the indication comprises at least one of a representation of the perceived environment annotated using information from the determined respective understanding, a navigation plan to enable an agent to navigate the perceived environment determined from the determined respective understanding, or a next step of a task to be completed by the agent in the perceived environment.

20. The system of claim 15, wherein the machine agent is further configured to:
navigate an agent through the at least one perceived environment using the developed understanding of the at least one perceived environment to locate at least one of an object or a location in the at least one perceived environment.

21. The system of claim 15, wherein the compact intermediate representation of the perceived environment is generated using at least one of a neural network or predetermined rules.

22. A non-transitory computer readable storage medium having stored thereon instructions that when executed by a processor perform a method for developing an understanding of at least one perceived environment, comprising:
determining semantic features and respective positional information of the semantic features from received data related to images and respective depth-related content of the at least one perceived environment on the fly as changes in the received data occur;
for each of the at least one perceived environments, combining information of the determined semantic features with the respective positional information to generate a compact intermediate representation of the perceived environment which provides information regarding positions of the semantic features in the perceived environment and at least spatial relationships among the sematic features;
for each of the at least one perceived environments, combining information from the determined intermediate representation with information stored in a foundational model to determine a respective understanding of the perceived environment; and
outputting an indication of the determined respective understanding of the perceived environment.
